(19) United States
(12) Patent Application Publication
(10) Pub. No.: US 2016/0169819 A1
(43) Pub. Date: Jun. 16, 2016

(54) SEMICONDUCTOR INSPECTION APPARATUS, SEMICONDUCTOR INSPECTION METHOD, AND RECORDING MEDIUM

(71) Applicant: Kabushiki Kaisha Toshiba, Minato-ku (JP)

(72) Inventor: Satoshi USUI, Nagoya (JP)

(73) Assignee: Kabushiki Kaisha Toshiba, Minato-ku (JP)

(21) Appl. No.: 14/847,243

(22) Filed: Sep. 8, 2015

(30) Foreign Application Priority Data
Dec. 16, 2014 (JP) 2014-254451

(51) Int. Cl. G01N 23/225; H01J 37/22; H01J 37/28

(52) U.S. Cl. CPC G01N 23/2251; H01J 37/28; H01J 37/222

(57) ABSTRACT

A semiconductor inspection apparatus according to an embodiment includes a calculator and an output unit. While a contour of an inspection object pattern on a semiconductor substrate and a closed curve obtained by approximation of the contour are superimposed on each other, the calculator acquires the total area of the area of the first region inside the contour and outside the closed curve and the area of the second region outside the contour and inside the closed curve. The calculator detects a defect in the inspection object pattern based on the total area. The output unit outputs data of the defect.

### CROSS REFERENCE TO RELATED APPLICATIONS

This application is based upon and claims the benefit of priority from the prior Japanese Patent Application No. 2014-254451, filed on Dec. 16, 2014, the entire contents of which are incorporated herein by reference.

### FIELD

Embodiments relate to a semiconductor inspection apparatus, a semiconductor inspection method, and a recording medium.

### BACKGROUND

When a semiconductor integrated circuit including an integrated circuit pattern is manufactured, a defect in the integrated circuit pattern is inspected. The defect inspection is performed by focusing on an item to be managed in the integrated circuit pattern. The item to be managed is different depending on the configuration of the semiconductor integrated circuit. For example, in some semiconductor integrated circuits, the shape of a circular hole pattern has to be managed in addition to a simple short circuit between patterns and a pattern open.

The defect inspection of an integrated circuit pattern has been performed based on a predetermined index in accordance with the integrated circuit pattern. For example, the defect in a circular hole pattern has been inspected based on the flattening ratio or the circularity.

However, these conventional indexes are insufficient for accurate inspection of the defect in an integrated circuit pattern.

### BRIEF DESCRIPTION OF THE DRAWINGS

FIG. 1 is a block diagram of a semiconductor inspection system 10 according to a first embodiment;

FIG. 2 is a flowchart showing an operation example of the semiconductor inspection system 10 of FIG. 1;

FIG. 3 is a schematic diagram showing a modification of an operation of the semiconductor inspection system 10 of FIG. 1;

FIG. 4A is a schematic diagram showing an inspection result in a case where a circular hole pattern does not satisfy the criterion for the flattening ratio, FIG. 4B is a schematic diagram showing an inspection result in a case where a circular hole pattern satisfies the criterion for the flattening ratio but does not satisfy the criterion for the total area, and FIG. 4C is a schematic diagram showing an inspection result in a case where a circular hole pattern satisfies both the criteria for the flattening ratio and the total area;

FIG. 5 is a block diagram of the semiconductor inspection system 10 according to a first modification of the first embodiment;

FIG. 6 is a flowchart of an operation example of the semiconductor inspection system 10 of FIG. 5;

FIG. 7 is a flowchart of an operation of the semiconductor inspection system 10 according to a second modification of the first embodiment;

FIG. 8 is a flowchart of an operation of the semiconductor inspection system 10 according to a second embodiment;

FIG. 9A is a schematic diagram showing a result of inspection in a first case where a circular hole pattern does not satisfy the criterion for the total area, FIG. 9B is a schematic diagram showing a result of inspection in a second case where a circular hole pattern does not satisfy the criterion for the total area, and FIG. 9C is a schematic diagram showing a result of inspection in a case where the circular hole pattern satisfies the criterion for the total area;

FIG. 10 is a flowchart of an operation of the semiconductor inspection system 10 according to a first modification of the second embodiment; and

FIG. 11 is a flowchart of an operation of the semiconductor inspection system 10 according to a second modification of the second embodiment.

### DETAILED DESCRIPTION

A semiconductor inspection apparatus according to an embodiment includes a calculator and an output unit. While a contour of an inspection object pattern on a semiconductor substrate and a closed curve obtained by approximation of the contour are superimposed on each other, the calculator acquires a total area of an area of a first region inside the contour and outside the closed curve and an area of a second region outside the contour and inside the closed curve. The calculator detects a defect in the inspection object pattern based on the total area. The output unit outputs data of the defect.

Embodiments will now be explained with reference to the accompanying drawings. The present invention is not limited to the embodiments.

### FIRST EMBODIMENT

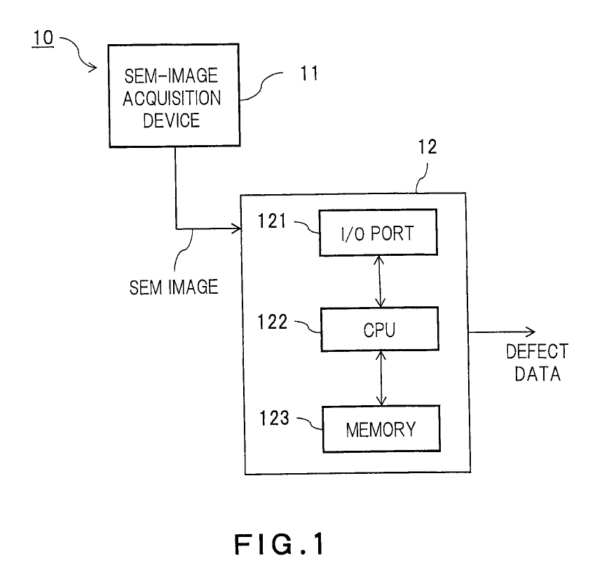

FIG. 1 is a block diagram of a semiconductor inspection system 10 according to a first embodiment. As shown in FIG. 1, the semiconductor inspection system 10 includes an SEM-image acquisition device 11 and a semiconductor inspection apparatus 12.

The SEM-image acquisition device 11 is a scanning electron microscope (SEM), for example. The SEM includes an electron gun that emits an electron beam towards a sample. The SEM also includes a detector that detects electrons (secondary electrons, reflected electron, or transmitted electrons), electromagnetic waves (X-rays or fluorescence), or the like radiated from the sample on which an electron beam is irradiated. Further, the SEM includes an image processor that converts electrons or electromagnetic waves detected by the detector into an SEM image (image data).

The SEM-image acquisition device 11 having this configuration emits an electron beam from the electron gun to a semiconductor substrate (a sample) having a circular hole pattern formed thereon in such a manner that an electron beam is directed to the circular hole pattern. The SEM-image acquisition device 11 detects electrons, electromagnetic waves, or the like radiated from the circular hole pattern in response to the irradiation of the electron beam by the detector. Further, the SEM-image acquisition device 11 converts the electrons or electromagnetic waves detected by the detector into an SEM image of the circular hole pattern in the image processor. The SEM-image acquisition device 11 then outputs the SEM image of the circular hole pattern to the semiconductor inspection apparatus 12.

The circular hole pattern is an example of an inspection object pattern, and is a memory hole (a hole layer) formed through a multilayer gate electrode of a three-dimensional multilayer memory, for example. The circular hole pattern may be a pattern such as a via hole, other than a memory hole. The circular hole pattern may be a pattern actually processed on the semiconductor substrate or a pattern formed in a resist arranged on the semiconductor substrate. The SEM image of the circular hole pattern may include an image of a configuration of the surroundings of the circular hole pattern.

The SEM-image acquisition device 11 is not limited to the SEM itself, as long as it is configured to be capable of acquiring an SEM image of a circular hole pattern. For example, the SEM-image acquisition device 11 may be a storage device connected to an SEM.

As shown in FIG. 1, the semiconductor inspection apparatus 12 includes an I/O port 121, a CPU 122, and a memory 123.

The I/O port 121 inputs an SEM image thereto. Also, the I/O port 121 (output unit) outputs defect data (described later) input from the CPU 122.

The CPU 122 is an example of a calculator. An SEM image of a circular hole pattern is input to the CPU 122 from the I/O port 121. The CPU 122 inspects a defect in the circular hole pattern based on the input SEM image of the circular hole pattern, from viewpoints of the shape and dimension of the circular hole pattern. For example, the CPU 122 detects the presence of a defect in the circular hole pattern in the defect inspection of the circular hole pattern. The CPU 122 may further detect the extent of the defect in the circular hole pattern. The CPU 122 outputs defect data indicating a result of the defect inspection of the circular hole pattern to the I/O port 121.

The memory 123 has stored therein a program that causes the CPU 122 (a computer) to perform a procedure of inspecting a circular hole pattern. The CPU 122 executes the program stored in the memory 123, thereby performing the defect inspection of the circular hole pattern.

The program stored in the memory 123 causes the CPU 122 to perform the following procedures (processes).
1. A first procedure of extracting a contour of a circular hole pattern based on an SEM image.
2. A second procedure of acquiring an elliptic curve by elliptic approximation of the contour of the circular hole pattern.
3. A third procedure of acquiring a flattening ratio of the elliptic curve.
4. A fourth procedure of acquiring the total area of the area of a first region inside the contour and outside the elliptic curve and the area of a second region outside the contour and inside the elliptic curve while the contour and the elliptic curve are superimposed on each other.
5. A fifth procedure of detecting a defect in the circular hole pattern based on the flattening ratio and the total area.

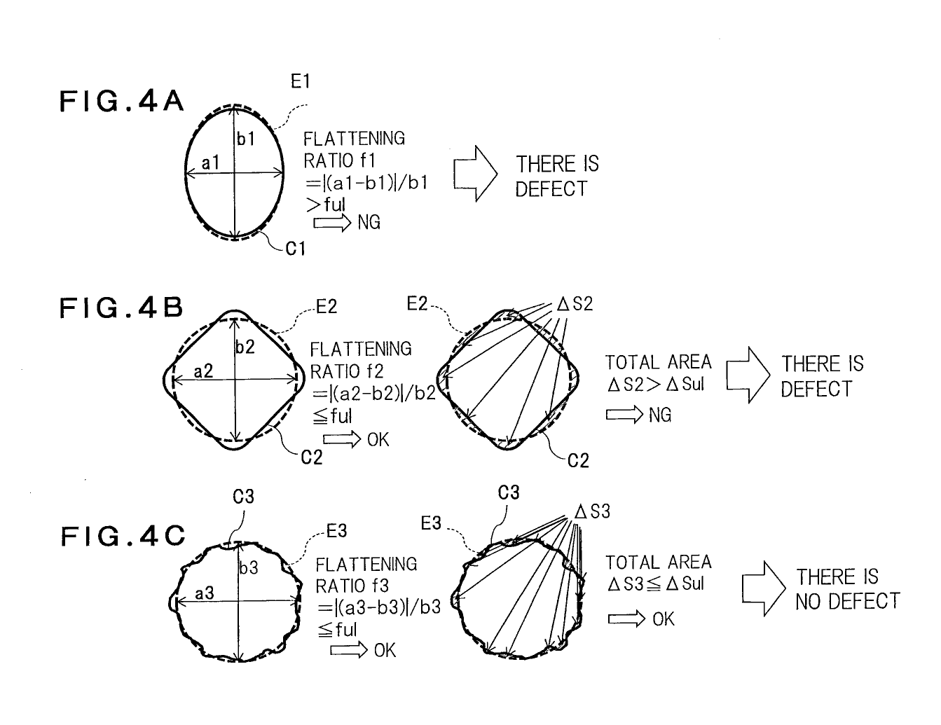

The first procedure is a procedure of extracting a contour (C1 in FIG. 4A, C2 in FIG. 4B, and C3 in FIG. 4C, for example) based on the contrast in the SEM image, for example.

The second procedure is a procedure of calculating an elliptic curve (E1 in FIG. 4A, E2 in FIG. 4B, and E3 in FIG. 4C, for example) by performing elliptic approximation of the contour of the circular hole pattern using the least squares method, for example.

The flattening ratio in the third procedure is one of indexes for inspecting a defect in a circular hole pattern. The third procedure is a procedure of calculating a flattening ratio by the following expression, for example.

f=|(a−b)|/b (1)

In Expression (1), f represents a flattening ratio, a represents the shortest diameter (that is, the minor axis) of an elliptic curve, and b represents the longest diameter (that is, the major axis) of the elliptic curve, for example. The a and b may respectively represent the longest diameter and the shortest diameter of the elliptic curve.

The total area in the fourth procedure (ΔS2 in FIG. 4B and ΔS3 in FIG. 4C, for example) is one of the indexes for inspecting a defect in a circular hole pattern. In a case where only the flattening ratio f is used as an index, it is difficult to perform the defect inspection of the circular hole pattern with high accuracy. Therefore, in the first embodiment, the total area is used as a further index. The total area can be considered as the area of a region corresponding to exclusive OR of a region surrounded by the contour and a region surrounded by the elliptic curve (an XOR area).

The fifth procedure is a procedure of detecting a defect in a circular hole pattern based on the criterion for the flattening ratio and the total area, for example. The criterion for the flattening ratio is that the flattening ratio is equal to or smaller than an upper limit (that is, a threshold value), for example. The CPU 122 may detect that the flattening ratio is larger than the upper limit, as a defect in the circular hole pattern. The criterion for the total area is that the total area is equal to or smaller than an upper limit (that is, a threshold value). The CPU 122 may detect that the total area is larger than the upper limit, as the defect in the circular hole pattern.

According to the semiconductor inspection system 10 of the first embodiment, it is possible to improve accuracy of the inspection of the circular hole pattern by using both indexes, that is, the flattening ratio and the total area.

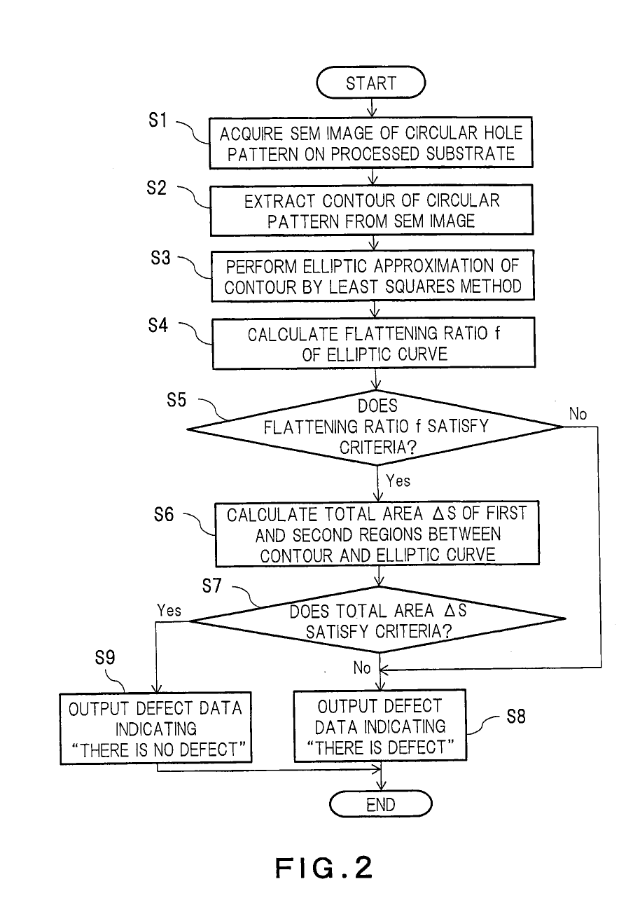

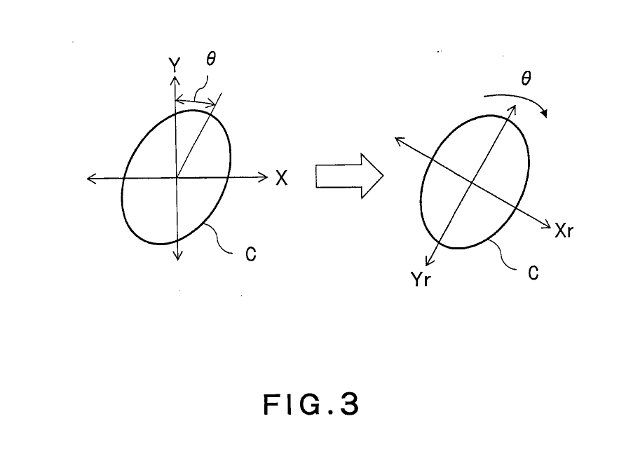

Next, with reference to FIGS. 2 to 4C, an operation example of the semiconductor inspection system 10 is described as an example of a semiconductor inspection method according to the first embodiment. FIG. 2 is a flowchart showing an example of an operation of the semiconductor inspection system 10 of FIG. 1. FIG. 3 is a schematic diagram showing a modification of an operation of the semiconductor inspection system 10 of FIG. 1. FIG. 4A is a schematic diagram showing an inspection result in a case where a circular hole pattern does not satisfy the criterion for the flattening ratio. FIG. 4B is a schematic diagram showing an inspection result in a case where a circular hole pattern satisfies the criterion for the flattening ratio but does not satisfy the criterion for the total area. FIG. 4C is a schematic diagram showing an inspection result in a case where a circular hole pattern satisfies both the criteria for the flattening ratio and the total area.

First, as shown in FIG. 2, the SEM-image acquisition device 11 acquires an SEM image of a circular hole pattern on a processed substrate (that is, a semiconductor substrate) (Step S1).

The CPU 122 then extracts the contour of the circular hole pattern from the SEM image of the circular hole pattern (Step S2). FIGS. 4A to 4C show contours having mutually different shapes as examples of the contour of the circular hole pattern. The contour C1 shown in FIG. 4A has a shape close to an ellipse. The contour C2 shown in FIG. 4B has a shape close to a square (that is, a rhombus). The contour C3 shown in FIG. 4C has an approximately circular shape having unevenness (roughness) formed by repeated meandering (that is, curving or waving) with a small radius of curvature.

As shown in FIG. 2, the CPU 122 then acquires an elliptic curve by performing elliptic approximation of the contour of the circular hole pattern, using the least squares method. In the elliptic approximation, the coordinates of a point on the contour are applied to a general expression of an ellipse in which the center of the ellipse, the shortest diameter, the longest diameter, the tilt (the rotation angle of the shortest diameter or the longest diameter) are unknown, for example. The coordinates here are an X-coordinate and a Y-coordinate in an SEM image coordinate system. Such application of coordinates to the general expression of the ellipse is performed for each of a plurality of points on the contour, so that the general expression after application of the coordinates is calculated for each point. Subsequently, the square of the general expression is calculated for the general expression after application of the coordinates for each point. The sum of the squares of the general expressions for the respective points is then calculated, and the center, the shortest diameter, the longest diameter, and the tilt are calculated in such a manner that the sum is minimized. This calculation uses a partial differentiation or a determinant, for example. If the tilt θ of the ellipse can be detected based on an angle θ formed by the direction of the largest diameter of the contour C and Y-axis, as shown in FIG. 3, a rotational coordinate system rotated by with respect to the SEM image coordinate system may be defined, and elliptic approximation may be performed using the coordinate axis (an Xr−Yr axis) of the rotational coordinate system as the basic axis. Because the ellipse is not tilted in the rotational coordinate system, calculation of the tilt can be omitted in the elliptic approximation using the coordinate axis of the rotational coordinate system as the basic axis. However, the mode of the elliptic approximation is not limited thereto.

FIGS. 4A to 4C show elliptic curves having mutually different shapes as examples of the elliptic curve. An elliptic curve E1 shown in FIG. 4A is obtained by elliptic approximation of a contour C1. An elliptic curve E2 shown in FIG. 4B is obtained by elliptic approximation of a contour C2. An elliptic curve E3 shown in FIG. 4C is obtained by elliptic approximation of a contour C3.

Subsequently, as shown in FIG. 2, the CPU 122 calculates the flattening ratio f of the elliptic curve. FIGS. 4A to 4C show flattening ratios of elliptic curves having mutually different shapes as examples of flattening ratios. A flattening ratio f1 of the elliptic curve E1 shown in FIG. 4A is |(a1−b1)|/b1. Because the difference between the shortest diameter a1 and the longest diameter b1 of the elliptic curve E1 is large, the flattening ratio f1 has a large value. A flattening ratio f2 of the elliptic curve E2 shown in FIG. 4B is |(a2−b2)|/b2. Because the difference between the shortest diameter a2 and the longest diameter b2 of the elliptic curve E2 is small, the flattening ratio f2 has a small value. A flattening ratio f3 of the elliptic curve E3 shown in FIG. 4C is |(a3−b3)|/b3. Because the difference between the shortest diameter a3 and the longest diameter b3 of the elliptic curve E3 is small, the flattening ratio f3 has a small value.

Next, as shown in FIG. 2, the CPU 122 determines whether the flattening ratio f satisfies the criterion (Step S5). When the flattening ratio f satisfies the criterion (YES at Step S5), the CPU 122 calculates the total area of the first and second regions between the contour and the elliptic curve (Step S6). Meanwhile, when the flattening ratio f does not satisfy the criterion (NO at Step S5), the CPU 122 outputs defect data indicating that “there is defect” (Step S8).

For example, the flattening ratio f1 of the elliptic curve E1 shown in FIG. 4A is larger than an upper limit ful (that is, the criterion is not satisfied). Therefore, the CPU 122 outputs defect data indicating that “there is defect” for the circular hole pattern having the contour C1. On the other hand, the flattening ratios f2 and f3 of the elliptic curves E2 and E3 shown in FIGS. 4B and 4C are equal to or smaller than the upper limit ful (that is, the criterion is satisfied). Therefore, the CPU 122 does not output the defect data indicating that “there is defect” for the circular hole patterns having the contours C2 and C3, and calculates the total area.

Next, as shown in FIG. 2, the CPU 122 determines whether a total area ΔS satisfies the criterion (Step S7). When the total area ΔS satisfies the criterion (YES at Step S7), the CPU 122 outputs defect data indicating that “there is no defect” (Step S9). When the total area ΔS does not satisfy the criterion (NO at Step S7), the CPU 122 outputs defect data indicating that “there is defect” (Step S8).

For example, the total area ΔS2 shown in FIG. 4B is larger than an upper limit ΔSul (that is, the criterion is not satisfied) because the difference of the shape between the contour C2 and the elliptic curve E2 is large. Therefore, the CPU 122 outputs defect data indicating that “there is defect” for the circular hole pattern having the contour C2. On the other hand, the total area ΔS3 shown in FIG. 4C is equal to or smaller than the upper limit ΔSul (that is, the criterion is satisfied) because the difference of the shape between the contour C3 and the elliptic curve E3 is small. Therefore, the CPU 122 outputs defect data indicating that “there is no defect” for the circular hole pattern having the contour C3.

In a case where the defect inspection of the circular hole pattern is performed using only the flattening ratio f as the index, it is possible to detect the defect in the circular hole pattern having the contour C1 of FIG. 4A, because it has a large flattening ratio f. However, because the circular hole pattern having the contour C2 shown in FIG. 4B has a small flattening ratio, it is not possible to detect the defect in the circular hole pattern although the shape of this circular hole pattern is far from a circular shape. Further, in a case where the defect inspection is performed using an evaluation value of the circularity, which is obtained by dividing the difference between the largest diameter and the smallest diameter of the contour by 2, as the index, the circular hole pattern having the contour C3 of FIG. 4C can be determined as having a large evaluation value (having a defect) although this pattern as a whole is close to a perfect circle. This is because the difference between the largest diameter and the smallest diameter in the circular hole pattern having the contour C3 of FIG. 4C can be locally large because of the roughness.

On the other hand, the first embodiment uses both the flattening ratio f and the total area ΔS as indexes, so that it is possible to suppress a failure of defect detection in the case of FIG. 4B and suppress erroneous defect detection in the case of FIG. 4C. That is, according to the first embodiment, it is possible to inspect the defect in the circular hole pattern with high accuracy (correctly).

### FIRST MODIFICATION

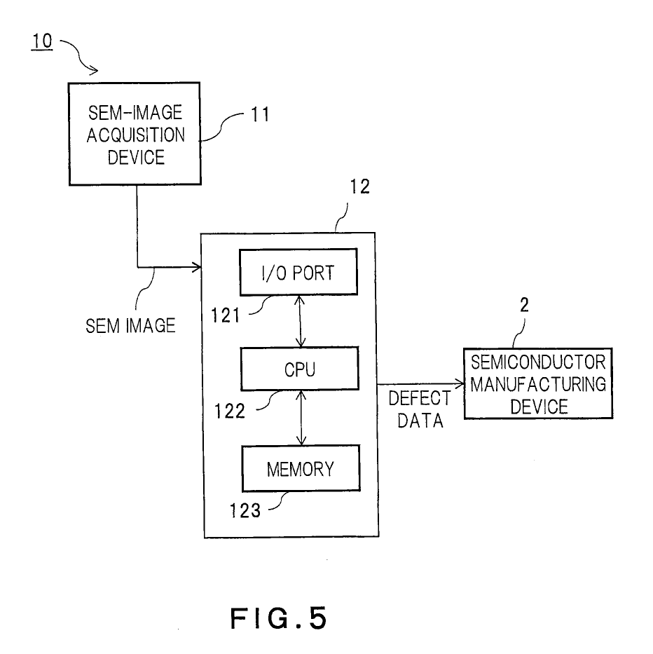

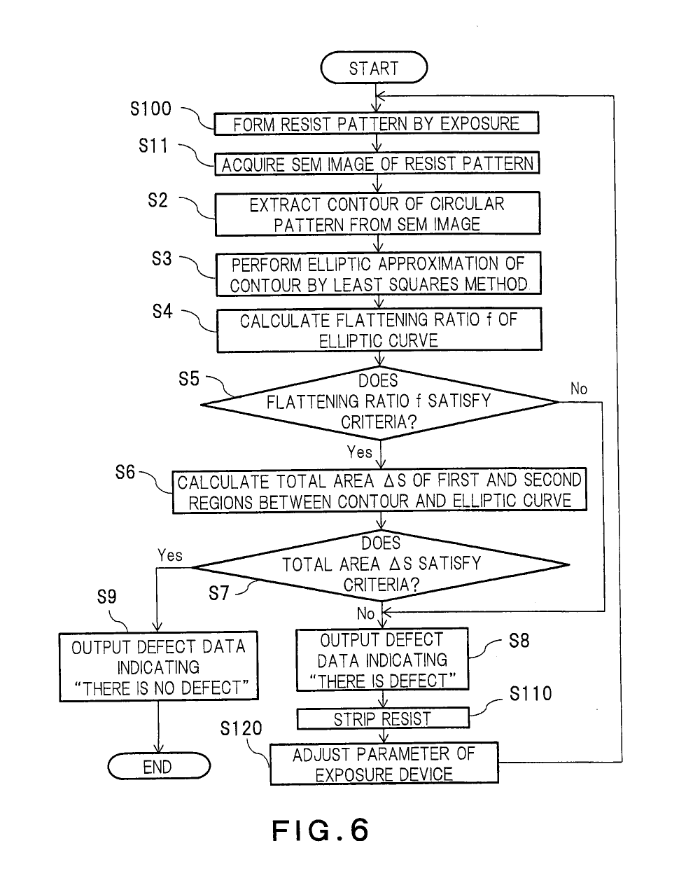

Next, with reference to FIGS. 5 and 6, a first modification of the first embodiment is described in which wafer rework is performed in accordance with a result of defect inspection of a circular hole pattern formed in a resist. In the descriptions of the first modification, constituent elements corresponding to those of the semiconductor inspection system 10 shown in FIG. 1 are denoted by like reference numerals, and redundant descriptions thereof will be omitted.

FIG. 5 is a block diagram of the semiconductor inspection system 10 according to the first modification of the first embodiment. FIG. 6 is a flowchart of an operation example of the semiconductor inspection system 10 of FIG. 5.

The semiconductor inspection system 10 of FIG. 5 includes a semiconductor manufacturing device 2 in addition to the configuration shown in FIG. 1. The semiconductor manufacturing device 2 includes an exposure device (not shown) and a resist stripping device. The semiconductor manufacturing device 2 forms a resist pattern having a circular hole on a semiconductor substrate with the exposure device. Further, the semiconductor manufacturing device 2 strips a resist pattern having a defect from the semiconductor substrate by the resist stripping device. The defect data output from the semiconductor inspection apparatus 12 is input to the semiconductor manufacturing device 2. The semiconductor manufacturing device 2 adjusts a parameter of the exposure device in accordance with the defect data input thereto. The parameter of the exposure device may be the amount of exposure, the wavelength, or the focal length, for example, but is not limited thereto.

An operation example of the semiconductor inspection system 10 according to the first modification is different from the example of the operation shown in FIG. 2 in the following features.

First, as shown in FIG. 6, the semiconductor manufacturing device 2 forms a resist pattern having a circular hole on a surface of a multilayer film formed on a semiconductor substrate by exposure by means of an exposure device (photolithography) (Step S100). The multilayer film is a multilayer gate electrode of a three-dimensional multilayer memory, for example. After formation of the resist pattern, the SEM-image acquisition device 11 acquires an SEM image of the resist pattern as an SEM image of the circular hole pattern (Step S11). Thereafter, the process shifts to Step S2. The semiconductor inspection system 10 may automatically transport the semiconductor substrate having the resist pattern formed thereon to the SEM-image acquisition device 11 by a transportation mechanism (not shown).

After Step S8, the semiconductor manufacturing device 2 strips the resist by the resist stripping device (Step S110). This process can be also referred to as “wafer rework process”. After stripping the resist, the semiconductor manufacturing device 2 adjusts the parameter of the exposure device (Step S120). The process then returns to Step S100.

In the first modification, when defect data indicating “there is no defect” (Step S9) is output, the semiconductor manufacturing device 2 can shift to a process of forming a circular hole pattern using a resist pattern.

According to the first modification, because the defect in the circular hole pattern can be detected in the resist, it is possible to reuse a wafer (a semiconductor substrate) by stripping the resist.

### SECOND MODIFICATION

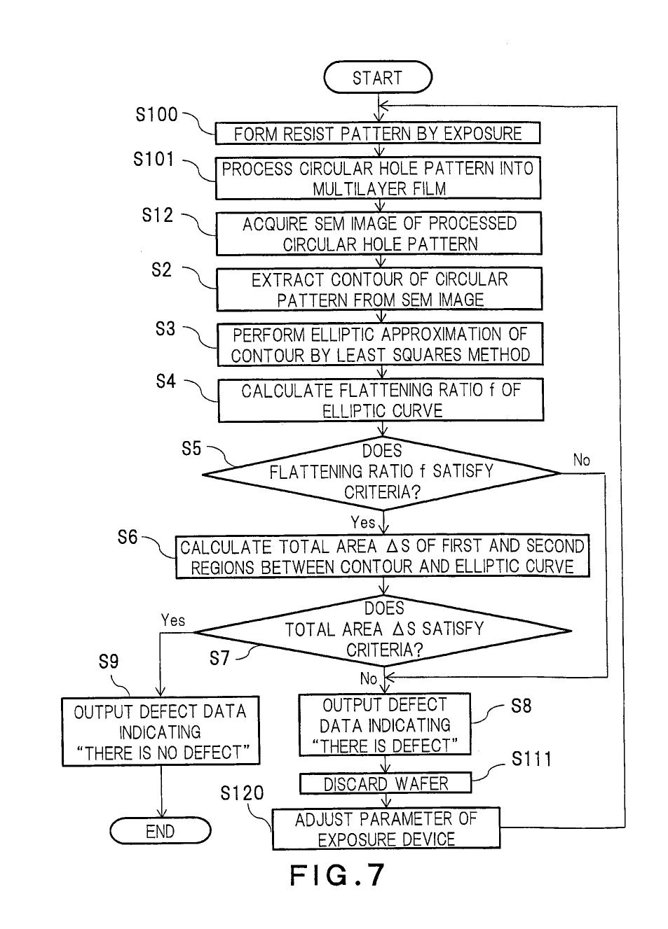

Next, with reference to FIG. 7, a second modification of the first embodiment is described, in which a defect in an actually formed circular hole pattern is inspected. In the descriptions of the second modification, constituent elements corresponding to those of the first modification are denoted by like reference numerals, and redundant descriptions thereof will be omitted.

FIG. 7 is a flowchart showing an operation example of the semiconductor inspection system 10 according to the second modification. The example of the operation of the semiconductor inspection system 10 according to the second modification is different from that in the first modification in the following features.

As shown in FIG. 7, after Step S100, the semiconductor manufacturing device 2 processes (that is, etches) the multilayer film to form a circular hole pattern by using a resist (Step S101). After the circular hole pattern is processed, the SEM-image acquisition device 11 acquires an SEM image of the processed circular hole pattern (Step S12). The process then shifts to Step S2.

After Step S8, the semiconductor inspection system 10 discards a wafer (Step S111). The discard of the wafer may be performed by automatic transportation of the wafer to a discard position by means of a transportation mechanism, for example. The process then shifts to Step S120.

According to the second modification, as an actually processed circular hole pattern is inspected, a defect can be detected with higher accuracy, as compared to the inspection of the circular hole pattern formed in the resist.

### SECOND EMBODIMENT

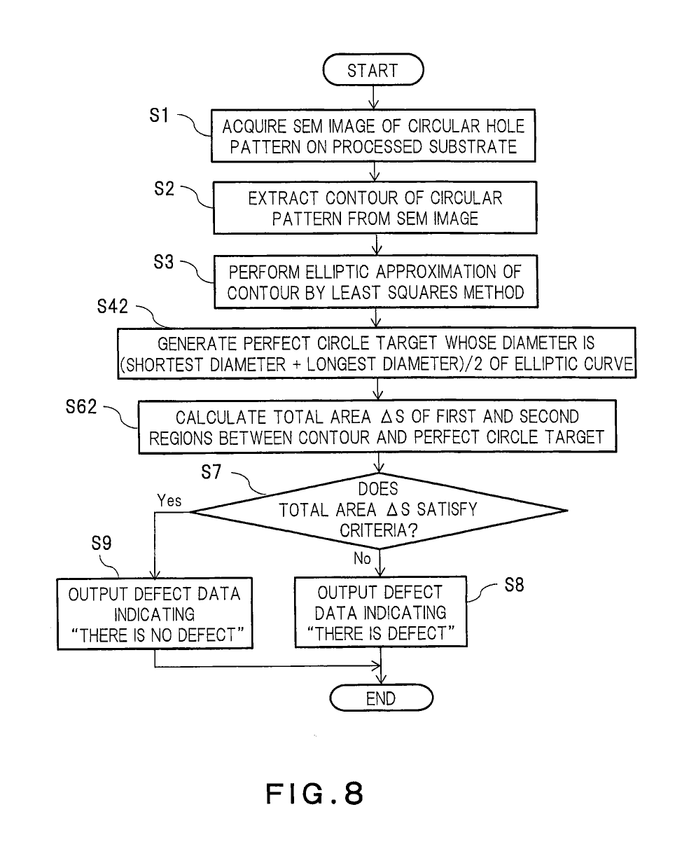

Next, with reference to FIGS. 8 to 11, an embodiment in which a defect in a circular hole pattern is inspected using a perfect circle target in place of the flattening ratio is described as a second embodiment. In the descriptions of the second embodiment, constituent elements corresponding to those of the semiconductor inspection system 10 shown in FIG. 1 are denoted by like reference numerals, and redundant descriptions thereof will be omitted.

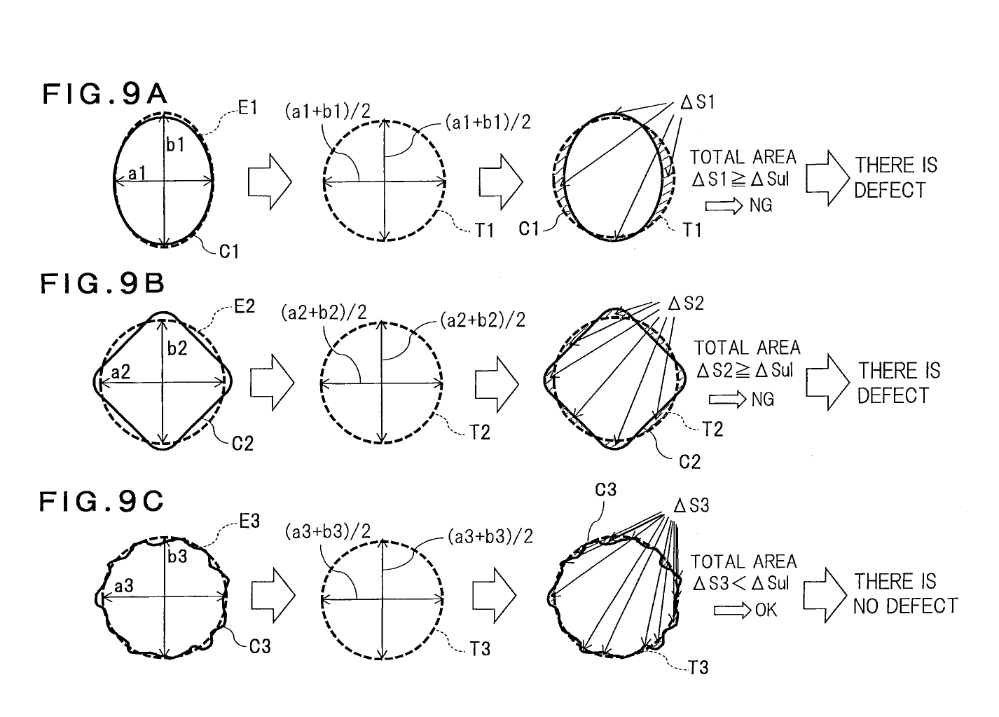

FIG. 8 is a flowchart of an operation of the semiconductor inspection system 10 according to the second embodiment. FIG. 9A is a schematic diagram showing a result of inspection in a first case where a circular hole pattern does not satisfy the criterion for the total area. FIG. 9B is a schematic diagram showing a result of inspection in a second case where a circular hole pattern does not satisfy the criterion for the total area. FIG. 9C is a schematic diagram showing a result of inspection in a case where a circular hole pattern satisfies the criterion for the total area.

The semiconductor inspection system 10 according to the second embodiment is different from that in the first embodiment in that it does not use the flattening ratio f as the index and in the mode of the total area ΔS.

Specifically, as shown in FIG. 8, after Step S3, the CPU 122 generates a perfect circle target (perfect circular curve) having a diameter equal to a half of the sum of the shortest diameter a and the longest diameter b of the elliptic curve (a+b)/2 (Step S42).

FIGS. 9A to 9C show elliptic curves E1 to E3 having mutually different shapes. Details of the elliptic curves E1 to E3 are the same as those in FIGS. 4A to 4C, respectively. The elliptic curves E1 to E3 are converted into perfect circle targets T1 to T3 in each of which the shortest diameter and the longest diameter of the corresponding elliptic curve are reflected.

As shown in FIG. 8, after generation of a perfect circle target, the CPU 122 calculates the total area ΔS of the first and second regions between the contour and the perfect circle target (Step S62). The process then shifts to Step S7.

FIGS. 9A to 9C show the total areas based on the contours having mutually different shapes. The total area ΔS1 shown in FIG. 9A has a large value because the difference between the contour C1 and the perfect circle target T1 is large. The total area ΔS2 shown in FIG. 9B also has a large value because the difference between the contour C2 and the perfect circle target T2 is large. On the other hand, the total area ΔS3 shown in FIG. 9C has a small value because the difference between the contour C3 and the perfect circle target T3 is small. The CPU 122 outputs defect data indicating “there is defect” for the circular hole patterns of FIGS. 9A and 9B based on the criterion for the total area ΔS, while outputting defect data indicating “there is no defect” for the circular hole pattern of FIG. 9C.

It can be said that the difference of the shape from the contour having a large flattening ratio appears more largely in the perfect circle target than in the elliptic curve. Therefore, it can be said that the flattening ratio is reflected more strongly on the total area based on the perfect circle target and the contour than on the total area based on the elliptic curve and the contour. Therefore, it can be said that the use of the total area based on the perfect circle target and the contour makes it possible to acquire the result of inspection on which the flattening ratio is reflected, without obtaining the flattening ratio. As a result, according to the second embodiment, calculation of the flattening ratio can be omitted.

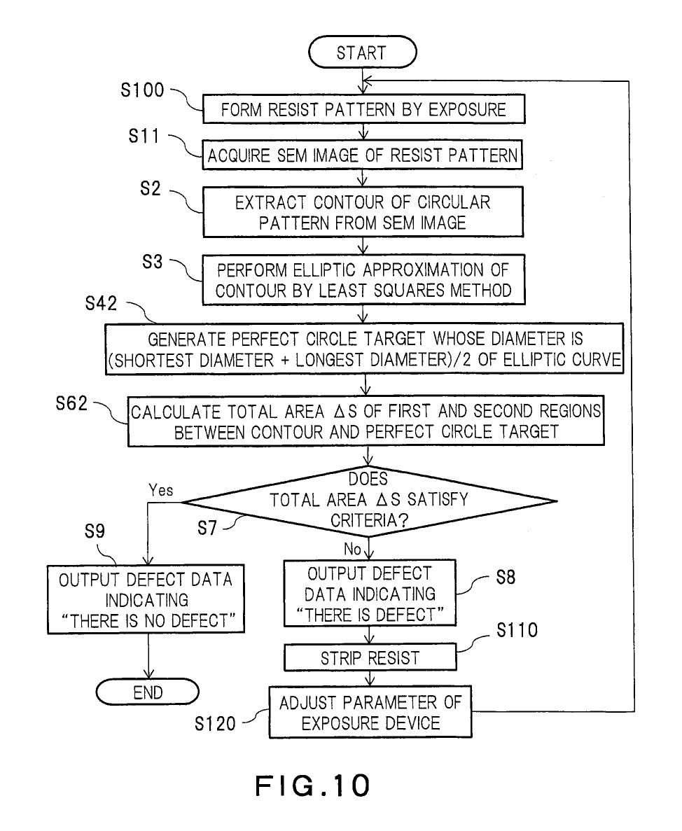

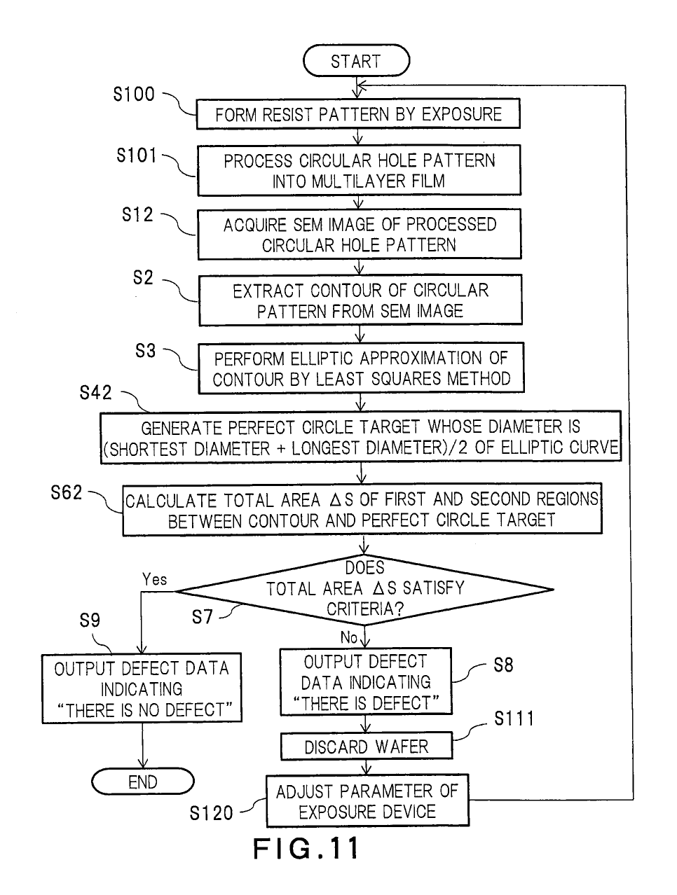

Furthermore, as shown in FIG. 10, a modification that uses the circular hole in the resist pattern as the inspection object can be also applied to the second embodiment, as in the first modification of the first embodiment. In addition, as shown in FIG. 11, the modification that uses the actual circular hole pattern as the inspection object can be applied to the second embodiment, as in the second modification of the first embodiment. Further, also in the second embodiment, elliptic approximation using the rotational coordinate system as the basic axis shown in FIG. 3 can be performed.

At least a part of the semiconductor inspection system according to the second embodiment may be formed by hardware or software. In the case of using software, a program that can achieve at least a part of the functions of the semiconductor inspection system may be stored in a recording medium such as a flexible disk or a CD-ROM, and the program is read into a computer and is executed by the computer. The recording medium is not limited to a removable medium such as a magnetic disk or an optical disk, but may be a fixed recording medium such as a hard disk device or a memory. Further, the program that can achieve at least a part of the functions of the semiconductor inspection system may be distributed via a communication line such as the Internet (including wireless communication). In addition, the program can be distributed via a wired line or a wireless line such as the Internet in a state where the program is encrypted, modulated, or compressed, or can be distributed as a program stored in a recording medium.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor inspection apparatus comprising:
a calculator that acquires a total area of an area of a first region inside a contour of an inspection object pattern on a semiconductor substrate and outside a closed curve obtained by approximation of the contour and an area of a second region outside the contour and inside the closed curve, while the contour and the closed curve are superimposed on each other, and detects a defect in the inspection object pattern based on the total area; and
an output unit configured to output data of the defect.

2. The apparatus of claim 1, wherein the inspection object pattern is a circular hole pattern, and the closed curve is a circular curve.

3. The apparatus of claim 2, wherein the circular curve is an elliptic curve obtained by elliptic approximation of the contour.

4. The apparatus of claim 2, wherein the circular curve is a perfect circular curve having a diameter based on a diameter of an elliptic curve obtained by elliptic approximation of the contour and a center that is same as a center of the elliptic curve.

5. The apparatus of claim 2, wherein the calculator acquires a flattening ratio of the inspection object pattern based on the closed curve, and detects the defect based also on the flattening ratio.

6. A semiconductor inspection method comprising:
acquiring a closed curve by approximation of a contour of an inspection object pattern on a semiconductor substrate;
acquiring a total area of an area of a first region inside the contour and outside the closed curve and an area of a second region outside the contour and inside the closed curve, while the contour and the closed curve are superimposed on each other; and
detecting a defect in the inspection object pattern based on the total area.

7. The method of claim 6, wherein the inspection object pattern is a circular hole pattern, and the closed curve is a circular curve.

8. The method of claim 7, wherein the circular curve is an elliptic curve obtained by elliptic approximation of the contour.

9. The method of claim 7, wherein the circular curve is a perfect circular curve having a diameter based on a diameter of an elliptic curve obtained by elliptic approximation of the contour and a center that is same as a center of the elliptic curve.

10. The method of claim 7, wherein a flattening ratio of the inspection object pattern is acquired based on the closed curve, and the defect is detected based also on the flattening ratio.

11. A computer-readable recording medium having recorded therein a semiconductor inspection program causing a computer to perform procedures of:
acquiring a closed curve by approximation of a contour of an inspection object pattern on a semiconductor substrate;
acquiring a total area of an area of a first region inside the contour and outside the closed curve and an area of a second region outside the contour and inside the closed curve, while the contour and the closed curve are superimposed on each other;
detecting a defect in the inspection object pattern based on the total area.

12. The recording medium of claim 11, wherein the inspection object pattern is a circular hole pattern, and the closed curve is a circular curve.

13. The recording medium of claim 12, wherein the circular curve is an elliptic curve obtained by elliptic approximation of the contour.

14. The recording medium of claim 12, wherein the circular curve is a perfect circular curve having a diameter based on a diameter of an elliptic curve obtained by elliptic approximation of the contour and a center that is same as a center of the elliptic curve.

15. The recording medium of claim 12, wherein, in the procedure of detecting a defect in the inspection object pattern based on the total area, a flattening ratio of the inspection object pattern is acquired based on the closed curve, and the defect is detected based also on the flattening ratio.
